(19) United States
(12) Patent Application Publication
(10) Pub. No.: US 2019/0369794 A1
(43) Pub. Date: Dec. 5, 2019

(54) LIGHT EMITTING DIODE DEVICE WITH TOUCH SENSING FUNCTION

(71) Applicant: GENERALPLUS TECHNOLOGY INC., Hsinchu City (TW)

(72) Inventors: Li-Sheng LO, Hsinchu County (TW); Hsien-Yao LI, Hsinchu City (TW)

(21) Appl. No.: 16/034,414

(22) Filed: Jul. 13, 2018

(30) Foreign Application Priority Data
Jun. 4, 2018 (TW) 107119233

(51) Int. Cl. G06F 3/041; G06F 3/044; H01L 25/075; H01L 25/16; H01L 33/62

(52) U.S. Cl. CPC G06F 3/0416; G06F 3/0412; H01L 33/62; H01L 25/0753; H01L 25/167; G06F 3/044

(57) ABSTRACT

A light emitting diode device includes plural display units and a micro control unit. Each display unit includes a light emitting diode having an anode and a cathode; an anode conductor sheet connected to the anode; and a cathode conductor sheet connected to the cathode. The anode conductor sheet and the cathode conductor sheet are arranged such that, during a display period, the light emitting diode is conducted and emits light; and, during a touch period, the light emitting diode is not conducted and does not emit light. The micro control unit is connected to the anode conductor sheet and the cathode conductor sheet and configured to connect the anode conductor sheet and the cathode conductor sheet to a display circuit during the display period, and to connect the anode conductor sheet and the cathode conductor sheet to a touch circuit during the touch period.

### BACKGROUND OF THE INVENTION

### 1. Field of the Invention

The present invention relates to a touch display device and, more particularly, to a light emitting diode device with touch sensing function.

### 2. Description of Related Art

Generally, a light emitting diode is an electroluminescent element that can be used for light emission and display. At present, it is desired to incorporate the light emitting diode display device with a touch mechanism to provide a touch display device.

FIG. 1 shows a prior art touch display device 7, in which the touch element is a photodiode 71. When the finger of a user touches the photodiode 71, the finger shields the light above the photodiode 71, so that a photocurrent of the photodiode 71 changes. By means of the photocurrent change, it is able to determine whether there is a touch event or not. Such a prior art touch display device 7 has at least one drawback that it is susceptible to ambient light, for example, it cannot be used normally in a dark room.

FIG. 2 shows another prior art touch display device 8, in which the light emitting element is a light emitting diode 81, and the touch element is a dedicated sensing electrode 82 arranged around the light emitting diode 81, which is thus independent (electrically insulated) from the light emitting diode 81. Such a prior touch display device 8 has at least three disadvantages: first, the dedicated sensing electrode 82 is an additional component, which in turn requires an additional component process for fabrication of component; second, a plurality of additional wirings are required to connect the dedicated sensing electrode 82 to a control chip, which in turn requires an additional wiring process for fabrication of wiring; third, the dedicated sensing electrode 82 and the plurality of additional wirings may cause a negative electrical or thermodynamic influence to the light emitting diode 81.

Therefore, it is desirable to provide an improved light emitting diode touch display device to mitigate and/or obviate the aforementioned problems.

### SUMMARY OF THE INVENTION

In view of the above, the present invention provides a light emitting diode device with touch sensing function, which comprises: at least one display unit and a micro control unit. The display unit comprises: a light emitting diode having an anode and a cathode; an anode conductor sheet connected to the anode of the light emitting diode; and a cathode conductor sheet connected to the cathode of the light emitting diode, wherein the anode conductor sheet and the cathode conductor sheet are arranged such that: during a display period, the light emitting diode is conducted and emits light; and during a touch period, the light emitting diode is not conducted and does not emit light, and they are suitable for sensing charges of a finger to generate a sensing signal. The micro control unit is connected to the anode conductor sheet and the cathode conductor sheet and configured to connect the anode conductor sheet and the cathode conductor sheet to a display circuit during the display period, and to connect the anode conductor sheet and the cathode conductor sheet to a touch circuit during the touch period.

Furthermore, in the light emitting diode device with touch sensing function, the display period and the touch period are generated alternately for the at least one display unit itself.

Furthermore, in the light emitting diode device with touch sensing function, a time-sharing switch mechanism is employed for the anode conductor sheet and the cathode conductor sheet.

Furthermore, in the light emitting diode device with touch sensing function, in addition to the anode conductor sheet and the cathode conductor sheet serving for transmitting the sensing signal during the touch period, there is no independent dedicated sensing electrode.

Furthermore, in the light emitting diode device with touch sensing function, any one of the anode conductor sheet and the cathode conductor sheet serves as a sensing electrode, or both of the anode conductor sheet and the cathode conductor sheet serve as sensing electrodes.

Furthermore, in the light emitting diode device with touch sensing function, a surface area of the cathode conductor sheet is larger than that of the anode conductor sheet, so that the cathode conductor sheet is suitable for serving as a sensing electrode.

Furthermore, in the light emitting diode device with touch sensing function, there are a plurality of switches disposed between the micro control unit, and the anode conductor sheet and the cathode conductor sheet for connecting the anode conductor sheet and the cathode conductor sheet to the display circuit or the touch circuit.

Furthermore, in the light emitting diode device with touch sensing function, during the touch period, the anode conductor sheet and the cathode conductor sheet are short-circuited to have an equal voltage thereby being suitable for performing a self-capacitance touch sensing. Particularly, the equal voltage is from the sensing signal and, when the anode conductor sheet and the cathode conductor sheet transmit the sensing signal of the equal voltage, the light emitting diode does not emit light. More particularly, the micro control unit connects the anode conductor sheet with the cathode conductor sheet in the touch circuit to short-circuit the anode conductor sheet and the cathode conductor sheet.

Furthermore, in the light emitting diode device with touch sensing function, during the touch period, the micro control unit enables the cathode conductor sheet to transmit a touch transmitting signal and enables the anode conductor sheet to receive a touch receiving signal, thereby being suitable for performing a mutual-capacitance touch sensing. Particularly, a difference between the touch transmitting signal and the touch receiving signal is proportional to the charges on the finger. More particularly, the touch transmitting signal is a high voltage and the touch receiving signal is a low voltage, so that, during the touch period, the light emitting diode is in reverse connection and does not emit light.

Furthermore, in the light emitting diode device with touch sensing function, the display unit is of a dual in-line package (DIP) light emitting diode structure or a surface mount device (SMD) light emitting diode structure.

Furthermore, the light emitting diode device with touch sensing function includes a plurality of display units, and the plurality of display units sequentially enter respective touch periods.

Furthermore, the light emitting diode device with touch sensing function includes a plurality of display units, and only some of specific display units of the plurality of display units sequentially enter respective touch periods. Particularly, the plurality of display units are divided into a plurality of groups, and the micro control unit is configured to determine a specific group of the plurality of groups that the sensing signal is from and, for the specific group, to determine a specific display unit of the specific group that the sensing signal is from.

Furthermore, the light emitting diode device with touch sensing function includes a plurality of display units arranged in an array.

Other objects, advantages, and novel features of the invention will become more apparent from the following detailed description when taken in conjunction with the accompanying drawings.

### BRIEF DESCRIPTION OF THE DRAWINGS

FIG. 1 shows a touch display device in the prior art;

FIG. 2 shows another touch display device in the prior art;

FIG. 3 is a block diagram showing a light emitting diode device with touch sensing function according to a first embodiment of the present invention;

FIG. 4 shows a display unit of a DIP structure;

FIG. 5 shows a display unit of an SMD structure;

FIG. 6 is a timing diagram showing that the display period and the touch period are generated alternately;

FIG. 7 is a schematic diagram showing a light emitting diode device with touch sensing function according to a second embodiment of the present invention;

FIG. 8 and FIG. 9 are schematic diagrams showing a light emitting diode device with touch sensing function according to a third embodiment of the present invention;

FIG. 10 shows a light emitting diode device with touch sensing function according to a fourth embodiment of the present invention;

FIG. 11 is a timing diagram showing a plurality of display units sequentially entering respective touch periods;

FIG. 12 and FIG. 13 show a light emitting diode device with touch sensing function according to a fifth embodiment of the present invention; and

FIG. 14 shows a light emitting diode device with touch sensing function according to a sixth embodiment of the present invention.

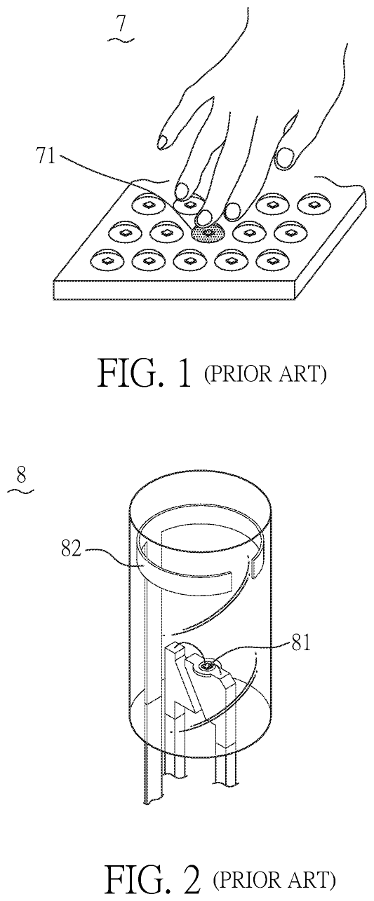

### DETAILED DESCRIPTION OF THE PREFERRED EMBODIMENT

The following embodiments when read with the accompanying drawings are made to clearly exhibit the above-mentioned and other technical contents, features and/or effects of the present invention. Through the exposition by means of the specific embodiments, people would further understand the technical means and effects the present invention adopts to achieve the above-indicated objectives. Moreover, as the contents disclosed herein should be readily understood and can be implemented by a person skilled in the art, all equivalent changes or modifications which do not depart from the concept of the present invention should be encompassed by the appended claims.

### First Embodiment

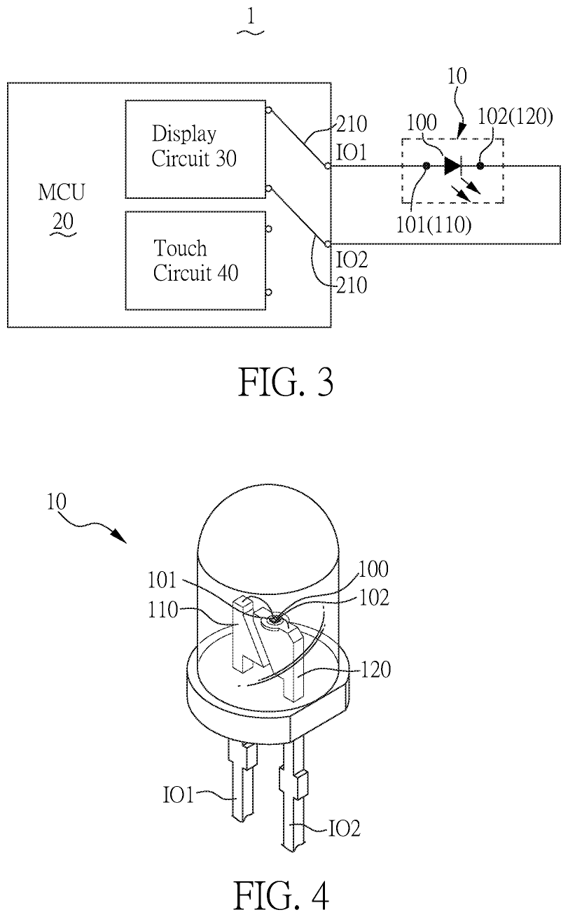

FIG. 3 is a block diagram showing a light emitting diode device with touch sensing function 1 according to a first embodiment of the present invention.

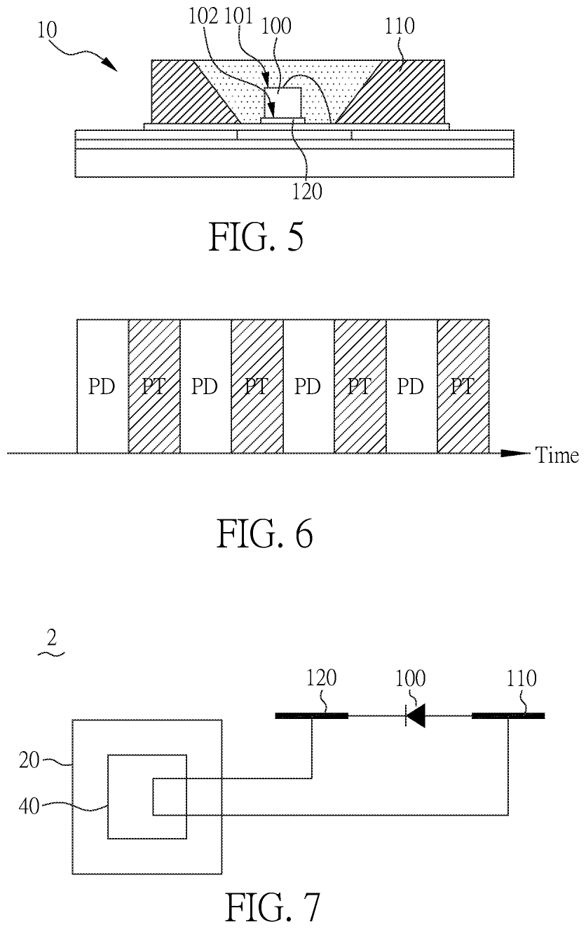

The light emitting diode device with touch sensing function 1 includes at least one display unit 1.0 and a micro control unit (MCU) 20. In one example, the display unit 10 can be of a dual in-line package (DIP) light emitting diode structure, as shown in FIG. 4. In another example, the display unit 10 can be of a surface mount device (SMD) light emitting diode structure, as shown in FIG. 5. Alternatively, other forms of display units are also applicable.

With reference to FIG. 3, FIG. 4 and FIG. 5, the display unit 10 includes: a light-emitting diode 100 including an anode 101 and a cathode 102; an anode conductor sheet 110 connected to the anode 101 of the light emitting diode 100; and a cathode conductor sheet 120 connected to the cathode 102 of the light emitting diode 100.

The anode conductor sheet 110 and the cathode conductor sheet 120 are arranged such that: the light emitting diode 100 is conducted and emits light during a display period PD; the light emitting diode 100 is not conducted and does not emit light during a touch period PT, and they are suitable for sensing the charges of a finger to generate a sensing signal.

In the present invention, it particularly senses the charges of a finger, instead of sensing light.

In addition, when observing a single display unit 10 itself, the display period PD and the touch period PT are generated alternately, as shown in the timing diagram of FIG. 6. In other words, in the present invention, a time-sharing switch mechanism is employed for the anode conductor sheet 110 and the cathode conductor sheet 120. The image switching frequency of a typical display device is at least greater than 60 Hz to avoid flicker sensed by human eyes. Furthermore, in the present invention, the timing is divided into the display period PD and the touch period PT, so that the time-sharing switch frequency is at least greater than 120 Hz to thus avoid flicker sensed by human eyes. Preferably, the time-sharing switch frequency is 120 Hz to 200 Hz to achieve a balance between visual effect and power saving effect. However, in case of being purely to avoid flicker sensed by human eyes, the time-sharing switch frequency may be greater than 200 Hz.

It is noted that the influence to the light emitting diode 100 must be considered when taking the anode conductor sheet 110 and the cathode conductor sheet 120 as the sensing electrodes. Specifically, during the touch period PT in which the anode conductor sheet 110 and the cathode conductor sheet 120 serve as the sensing electrodes to transmit the sensing signal, a voltage of the sensing signal may cause the light emitting diode 100 to emit light unexpectedly. For example, the light emitting diode 100 emits light unexpectedly when there is no need to emit light, or emits light that is too bright or too dark. Therefore, the anode conductor sheet 110 and the cathode conductor sheet 120 must be arranged such that, during the touch period PT, the light emitting diode 100 is not conducted and does not emit light. This arrangement is important.

In the present invention, any one of the anode conductor sheet 110 and the cathode conductor sheet 120 may be selected as a sensing electrode; in other words, the other one may be idle and not used. In the case where only a single sensing electrode is used, since the cathode conductor sheet 120 needs to transmit a higher voltage, the size of the cathode conductor sheet 120 is designed to be larger than that of the anode conductor sheet 110, and thus the surface area of the cathode conductor sheet 120 is also larger than that of the anode conductor sheet 110, as shown in FIG. 4, so that the cathode conductor sheet 120 is more suitable for serving as a sensing electrode. (It is noted that, the anode conductor sheet 110 transmits a high voltage during the display period, and the cathode conductor sheet 120 transmits a high voltage during the touch period. However, the present invention suggests the surface area in consideration of the purpose of touch control). It is further noted that, in the case where only a single sensing electrode is used, a self-capacitance sensing method must be adopted.

Preferably, the anode conductor sheet 110 and the cathode conductor sheet 120 are both selected to serve as a sensing electrode, and the two conductor sheets are electrically connected with each other to perform a self-capacitance sensing method, or the two conductor sheets are electrically independent from each other to perform a mutual-capacitance sensing method. These sensing methods will be further explained in the subsequent paragraphs.

The micro control unit 20 is connected to the anode conductor sheet 110 and the cathode conductor sheet 120 via an anode node 101 and a cathode node 102, respectively. The micro control unit 20 is configured such that, during the display period PD, the anode conductor sheet 110 and the cathode conductor sheet 120 are connected to a display circuit 30 and, during the touch period PT, the anode conductor sheet 110 and the cathode conductor sheet 120 are connected to a touch circuit 40. The display circuit 30 is provided to turn on the at least one display unit 10, typically a display unit matrix, during the display period PD, so as to display an image. The touch circuit 40 is provided to perform a touch sensing during the touch period PT by using the anode conductor sheet 110 or the cathode conductor sheet 120, or by using both (according to a predetermined design).

Specifically, there are a plurality of switches 210 disposed between the micro control unit 20, and the anode conductor sheet 110 and the cathode conductor sheet 120 for connecting the anode conductor sheet 110 and the cathode conductor sheet 120 to the display circuit 30 or the touch circuit 40.

As an example, the operation flow of the micro control unit 20 includes: first, controlling the light emission and display of the display unit 10; then, switching the display unit 10 from being connected with the display circuit 30 to being connected with the touch circuit 40 (at this time, the light emitting diode 100 is floated with respect to the display circuit 30); then, controlling the touch sensing of the display unit 10; and then, determining the result of the touch sensing. The process then goes to controlling the light emission and display of the display unit 10 so as to repeat the operation flow.

It can be seen that the anode conductor sheet 110 and the cathode conductor sheet 120 of the present invention not only serve as electrodes of the light emitting diode 100 but also serve as sensing electrodes, and a time-sharing switch mechanism is adopted to switch the conductor sheets between serving as light emitting diode electrodes and serving as sensing electrodes.

Therefore, in addition to the anode conductor sheet 110 and the cathode conductor sheet 120 serving for transmitting the sensing signal during the touch period PT, there is no independent dedicated sensing electrode in the present invention. As a result, there is no need to have additional sensing electrodes and the manufacturing process thereof, and there is also no need to have additional sensing wirings and the manufacturing process thereof, while there is no adverse electrical or thermodynamic influence to the light emitting diode 100 caused by the presence of the aforementioned additional components.

### Second Embodiment

FIG. 7 is a schematic diagram showing a light emitting diode device with touch sensing function 2 according to a second embodiment of the present invention, which is suitable for performing a self-capacitance touch sensing.

With the self-capacitive touch sensing, only a single sensing electrode is used to sense whether a touch event occurs in a minimum sensing unit, and the sensing electrode is responsible for both the sensing signal transmission and the sensing signal reception. It is noted that, if there are a plurality of minimum sensing units, each of the minimum sensing units is provided with a single sensing electrode. By using the difference between the transmitted sensing signal and the received sensing signal, it is able to determine whether a touch event occurs.

As for the case where only the anode conductor sheet 110 is used or only the cathode conductor sheet 120 is used, the touch operation is similar to the aforementioned example, and thus a detailed description therefor is deemed unnecessary.

In the example specifically described in this embodiment, during the touch period PT, the micro control unit 20 causes the anode conductor sheet 110 and the cathode conductor sheet 120 to be short-circuited, so as to have an equal voltage thereby being suitable for performing a self-capacitance touch sensing. Specifically, the equal voltage is from the sensing signal and, when the anode conductor sheet 110 and the cathode conductor sheet 120 transmit the sensing signal of the equal voltage, the light emitting diode 100 does not emit light.

The short circuit is provided by the control of the micro control unit 20 to connect the anode conductor sheet 110 with the cathode conductor sheet 120 in the touch circuit 40. The aforementioned connection can be implemented by using a plurality of switches (for example, a logic circuit composed of transistors)

It is noted that, because the transmission of the sensing signal, the equal voltage can be a non-zero voltage (non-ground voltage). This shows a distinct feature of the present invention. Since the anode and the cathode of a typical light emitting diode purely for light emission are not short-circuited under normal operation and thus do not have non-zero voltage (non-ground voltage). However, according to the present invention, the anode conductor sheet 110 and the cathode conductor sheet 120 are used for both light emission and sensing, so that it is necessary to short-circuit the anode conductor sheet 110 and the cathode conductor sheet 120 during the touch period to form a sensing electrode.

It is further noted that, in addition to provision of self-capacitance touch sensing, the use of short circuit has two advantages: first, the anode conductor sheet 110 and the cathode conductor sheet 120 are combined together by short circuit so as to provide a larger sensing area, while there is no reason to combine two separate conductor sheets by short circuit in the prior art; second, since the anode conductor sheet 110 and the cathode conductor sheet 120 have the same voltage by short circuit, the light emitting diode 100 does not emit light unexpectedly due to that there is no voltage difference between the anode and the cathode.

### Third Embodiment

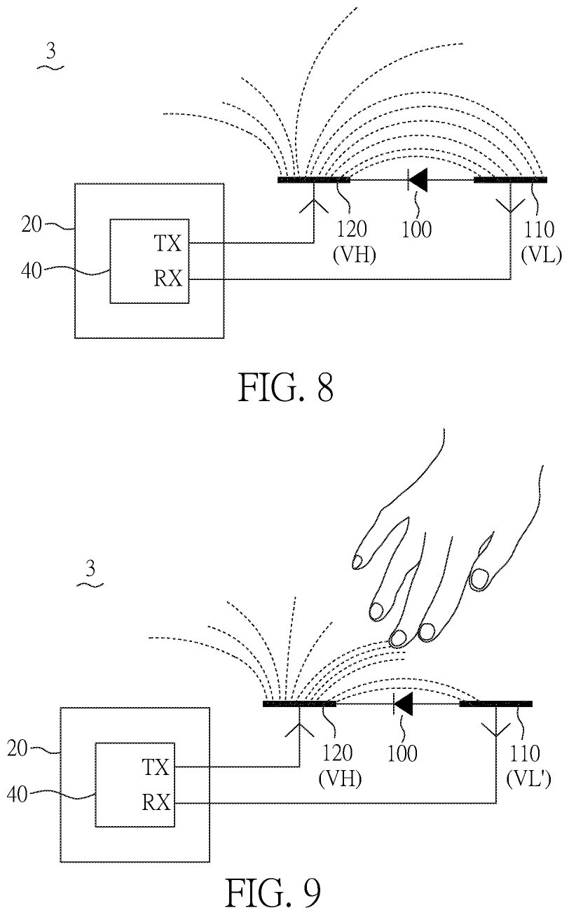

FIG. 8 is a schematic diagram showing a light emitting diode device with touch sensing function 3 according to a third embodiment of the present, which is suitable for performing a mutual-capacitance touch sensing.

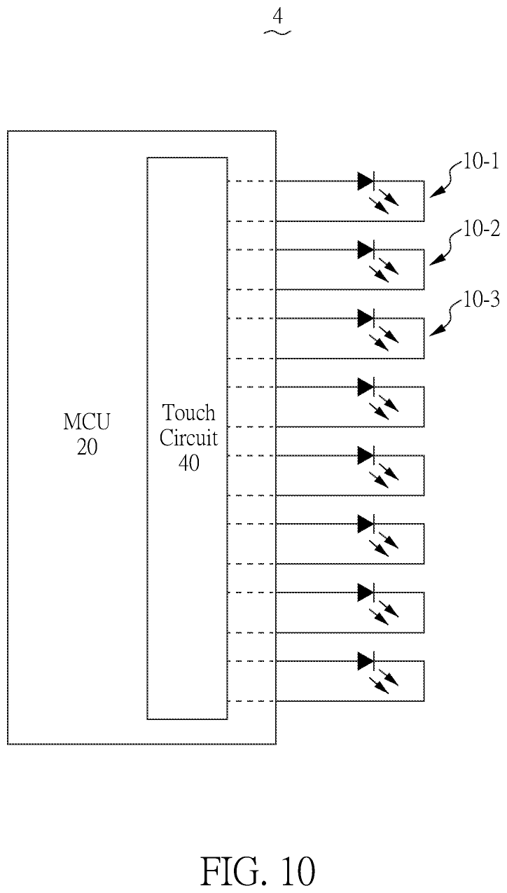

In the mutual-capacitance touch sensing of the present invention, a touch transmitting electrode (i.e., the cathode conductor sheet 120) is used to transmit a touch transmitting signal TX, and a touch receiving electrode (i.e., the anode conductor sheet 110) is used to receive a touch receiving signal RX. If a finger approaches the touch transmitting electrode and the touch receiving electrode, the charges on the finger may block or weaken the touch transmitting signal TX transmitted from the touch transmitting electrode. As shown in FIG. 9, the finger blocks a portion of the electric flux lines between the touch transmitting electrode and the touch receiving electrode. Then, the touch receiving electrode receives the blocked or weakened touch transmitting signal TX to form the touch receiving signal RX. By comparing the touch transmitting signal TX with the touch receiving signal RX to have a difference, it is able to determine whether a touch event occurs. In other words, the difference between the touch transmitting signal TX and the touch receiving signal RX is proportional to the charges on one finger.

According to the present invention, during the touch period PT, the micro control unit 20 controls the cathode conductor sheet 120 to transmit a touch transmitting signal TX, and the anode conductor sheet 110 receives a touch receiving signal RX. Preferably, the touch transmitting signal. TX is a high voltage VH, and the touch receiving signal RX is a low voltage VL, so that the light emitting diode 100 is in reverse connection during the touch period and thus does not emit light.

As described above, since the anode conductor sheet 110 and the cathode conductor sheet 120 of the present invention may serve as both the electrodes of the light emitting diode 100 and the sensing electrodes, the influence to the light emitting diode 100 has to be considered when the anode conductor sheet 110 and the cathode conductor sheet 120 serve as the sensing electrodes, so as to prevent the light emitting diode 100 from unexpected light emission. Therefore, with the reverse connection for generating a reverse voltage to the light emitting diode 100, it is able to prevent the light emitting diode 100 from unexpected light emission.

### Fourth Embodiment

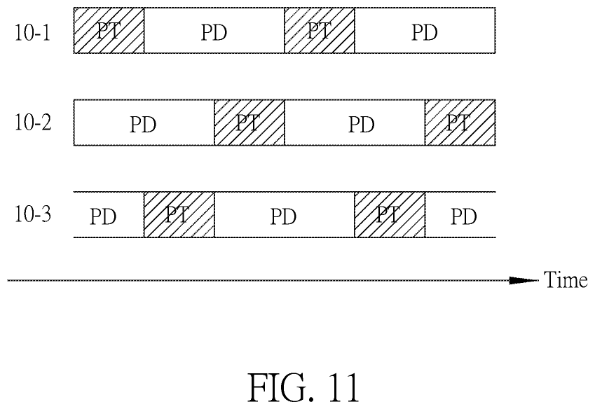

FIG. 10 shows a light emitting diode device with touch sensing function 4 according to a fourth embodiment of the present invention (the display circuit 30 exists, but is not shown in FIG. 10), which includes a plurality of display units 10, labeled as 10-1, 10-2, 10-3, and so on, for example. Each display unit 10 has the same structure as the display unit of the first embodiment, and the plurality of display units 10 sequentially enter their respective touch periods PT. Because the touch sensing needs to sequentially scan each of the minimum. sensing units to determine the position of a touch event, the timing diagram showing the plurality of display units 10 sequentially entering the respective touch periods PT is given in FIG. 11.

### Fifth Embodiment

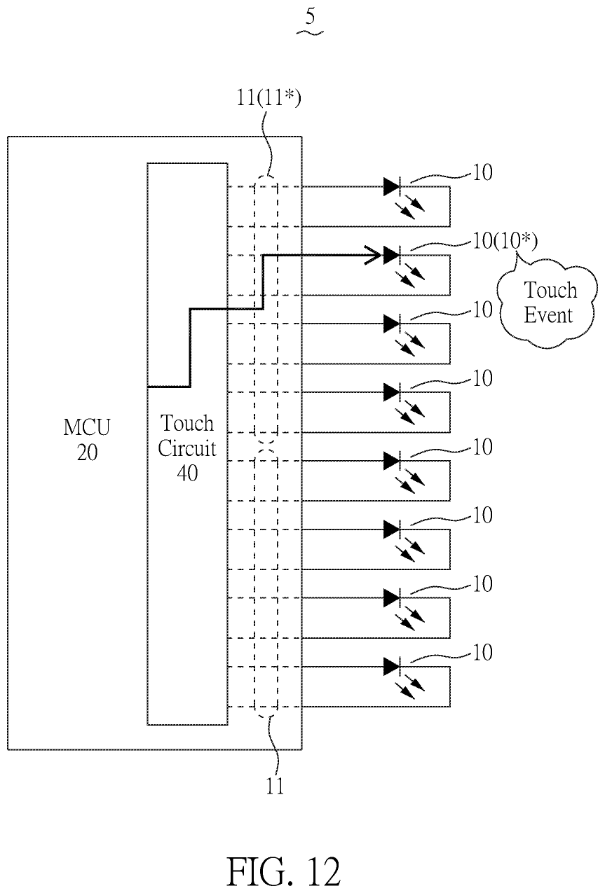

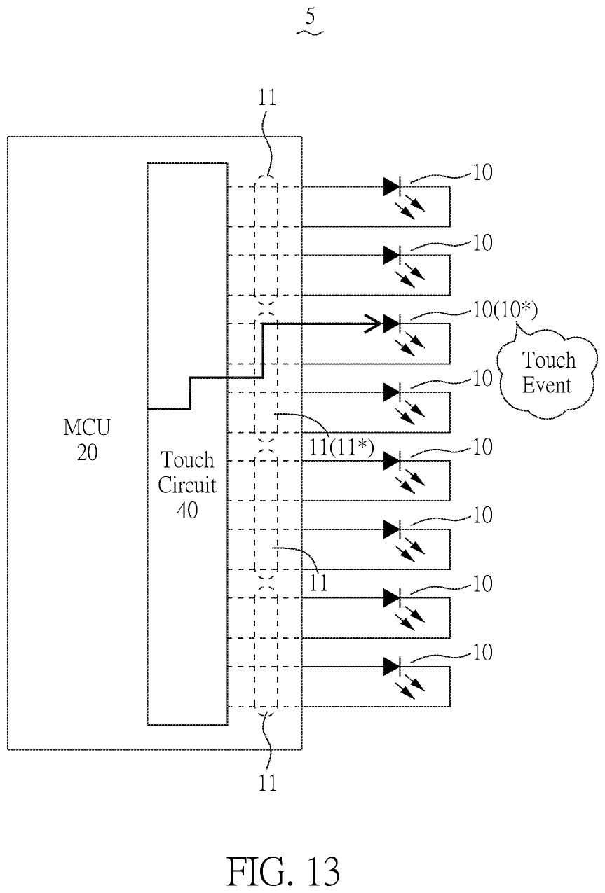

FIG. 12 and FIG. 13 show a light emitting diode device with touch sensing function 5 according to a fifth embodiment of the present invention (the display circuit 30 exists, but is not shown in FIG. 12 and FIG. 13), which includes a plurality of display units 10, while only some of specific display units 10 of the plurality of display units 10 sequentially enter the respective touch periods PT.

Specifically, the plurality of display units 10 are divided into a plurality of groups 11, and the micro control unit 20 is configured to determine a specific group 11* of the plurality of groups 11 that the sensing signal is from and, for the specific group 11*, to determine a specific display unit 10* of the specific group 11* that the sensing signal is from. The dashed lines of FIG. 12 and. FIG. 13 show a decision path in accordance with the aforementioned configuration. In FIG. 12 and FIG. 13, eight display units 10 are divided into different numbers of groups, respectively. Specifically, in FIG. 12, the eight display units 10 are divided into two groups and, in FIG. 13, the eight display units 10 are divided into four groups, while other grouping methods are also possible.

In other words, in addition to the specific group 11*, there is no need to perform a touch scanning on the other groups 11 so as to save time and power.

### Sixth Embodiment

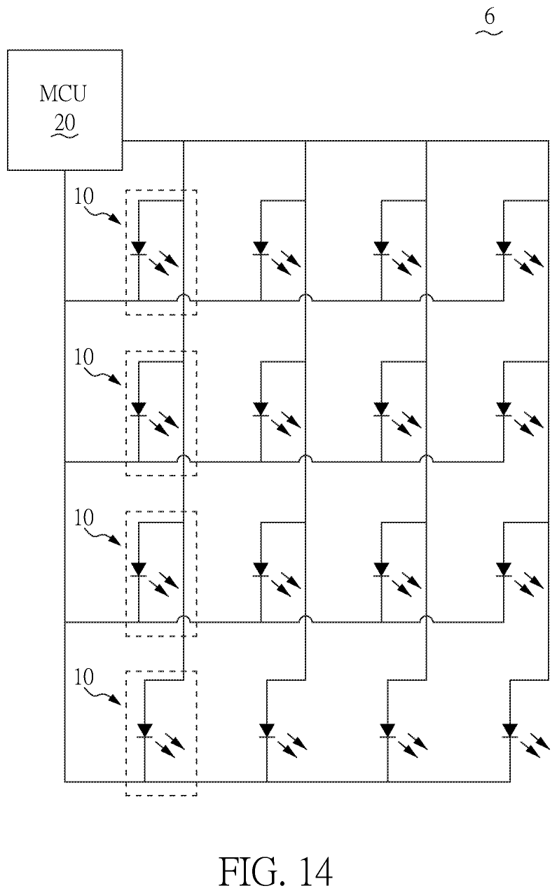

FIG. 14 shows a light emitting diode device with touch sensing function 6 according to a sixth embodiment of the present invention, which includes a plurality of display units 10. The plurality of display units 10 are arranged in an array, wherein the structure and the operation for each display unit 10 are similar to those of the previous embodiment and thus a detailed description therefor is deemed unnecessary.

In summary, in the present invention, there is no independent dedicated sensing electrode in addition to that the anode conductor sheet and the cathode conductor sheet are used to transmit the sensing signal during the touch period. As a result, there is no need to have additional sensing electrodes and the manufacturing process thereof, and there is also no need to have additional sensing wirings and the manufacturing process thereof, while there is no adverse electrical or thermodynamic influence to the light emitting diode caused by the presence of the aforementioned additional components.

In addition, in further aspects of the present invention, in consideration of an influence to the light emitting diode caused by using the anode conductor sheet and the cathode conductor sheet as sensing electrodes, a short circuit connection method and a reverse voltage application method are designed for the anode conductor sheet and the cathode conductor sheet to prevent the light emitting diode from unexpected light emission during the touch period.

Although the present invention has been explained in relation to its preferred embodiment, it is to be understood that many other possible modifications and variations can be made without departing from the spirit and scope of the invention as hereinafter claimed.

What is claimed is:

1. A light emitting diode device with touch sensing function, comprising:
at least one display unit comprising:
a light emitting diode having an anode and a cathode;
an anode conductor sheet connected to the anode of the light emitting diode; and
a cathode conductor sheet connected to the cathode of the light emitting diode,
wherein the anode conductor sheet and the cathode conductor sheet are arranged such that:
during a display period, the light emitting diode is conducted and emits light; and
during a touch period, the light emitting diode is not conducted and does not emit light, and the anode conductor sheet and the cathode conductor sheet are suitable for sensing charges of a finger to generate a sensing signal; and
a micro control unit connected to the anode conductor sheet and the cathode conductor sheet and configured to connect the anode conductor sheet and the cathode conductor sheet to a display circuit during the display period, and to connect the anode conductor sheet and the cathode conductor sheet to a touch circuit during the touch period.

2. The light emitting diode device with touch sensing function as claimed in claim 1, wherein the display period and the touch period are generated alternately for the at least one display unit itself.

3. The light emitting diode device with touch sensing function as claimed in claim 1, wherein, in addition to the anode conductor sheet and the cathode conductor sheet serving for transmitting the sensing signal during the touch period, there is no independent dedicated sensing electrode.

4. The light emitting diode device with touch sensing function as claimed in claim 1, wherein any one of the anode conductor sheet and the cathode conductor sheet serves as a sensing electrode, or both of the anode conductor sheet and the cathode conductor sheet serve as sensing electrodes.

5. The light emitting diode device with touch sensing function as claimed in claim 1, wherein a surface area of the cathode conductor sheet is larger than that of the anode conductor sheet, so that the cathode conductor sheet is suitable for serving as a sensing electrode.

6. The light emitting diode device with touch sensing function as claimed in claim 1, wherein there are a plurality of switches disposed between the micro control unit, and the anode conductor sheet and the cathode conductor sheet for connecting the anode conductor sheet and the cathode conductor sheet to the display circuit or the touch circuit.

7. The light emitting diode device with touch sensing function as claimed in claim 1, wherein, during the touch period, the anode conductor sheet and the cathode conductor sheet are short-circuited to have an equal voltage thereby being suitable for performing a self-capacitance touch sensing.

8. The light emitting diode device with touch sensing function as claimed in claim 7, wherein the equal voltage is from the sensing signal and, when the anode conductor sheet and the cathode conductor sheet transmit the sensing signal of the equal voltage, the light emitting diode does not emit light.

9. The light emitting diode device with touch sensing function as claimed in claim 7, wherein the micro control unit connects the anode conductor sheet with the cathode conductor sheet in the touch circuit to short-circuit the anode conductor sheet and the cathode conductor sheet.

10. The light emitting diode device with touch sensing function as claimed in claim 1, wherein, during the touch period, the micro control unit enables the cathode conductor sheet to transmit a touch transmitting signal and enables the anode conductor sheet to receive a touch receiving signal, thereby being suitable for performing a mutual-capacitance touch sensing.

11. The light emitting diode device with touch sensing function as claimed in claim 10, wherein, a difference between the touch transmitting signal and the touch receiving signal is proportional to the charges on the finger.

12. The light emitting diode device with touch sensing function as claimed in claim 10, wherein the touch transmitting signal is a high voltage and the touch receiving signal is a low voltage, so that, during the touch period, the light emitting diode is in reverse connection and does not emit light.

13. The light emitting diode device with touch sensing function as claimed in claim 1, wherein the display unit is of a dual in-line package (DIP) light emitting diode structure or a surface mount device (SMD) light emitting diode structure.

14. The light emitting diode device with touch sensing function as claimed in claim 1, wherein the at least one display unit includes a plurality of display units, and the plurality of display units sequentially enter respective touch periods.

15. The light emitting diode device with touch sensing function as claimed in claim 1, wherein the at least one display unit includes a plurality of display units, and only some of specific display units of the plurality of display units sequentially enter respective touch periods.

16. The light emitting diode device with touch sensing function as claimed in claim 15, wherein the plurality of display units are divided into a plurality of groups, and the micro control unit is configured to determine a specific group of the plurality of groups that the sensing signal is from and, for the specific group, to determine a specific display unit of the specific group that the sensing signal is from.

17. The light emitting diode device with touch sensing function as claimed in claim 1, wherein the at least one display unit includes a plurality of display units, and the plurality of display units are arranged in an array.
